(19) United States
(12) Patent Application Publication
(10) Pub. No.: US 2026/0343764 A1
(43) Pub. Date: Oct. 29, 2026

(54) ELECTRICALLY ISOLATED MULTI-CIRCUIT COMPONENT HOUSING

(71) Applicant: Nairobi Incorporated, Scottsdale, AZ (US)

(72) Inventors: Justin Eugene Evans, New Taipei City (TW); Shuaib Naseem Badat, Cape Town (ZA)

(21) Appl. No.: 19/189,313

(22) Filed: Apr. 25, 2025

(51) Int. Cl. H05K 5/02

(52) U.S. Cl. CPC H05K 5/0247

(57) ABSTRACT

A component housing includes a structural body configured with first passages and second passages that receive respective sets of electrical conductors associated with first and second electrical circuits. The first and second circuits are electrically independent and generate distinct electromagnetic fields. The structural body can be formed from an electrically insulating or dielectric material and can maintain physical and electrical isolation between the two sets of conductors such that the electromagnetic fields coexist within the housing without mutual interference. In some embodiments, the first passages are configured to accommodate high-voltage conductors and the second passages low-voltage conductors. The structural body can be monolithic or assembled from separate sections and include insulating members disposed in one or more of the passages. The housing includes structural supports and spaces configured to receive and retain an electrical component, and one or more outlets for conductor access positioned on various sides of the housing.

### FIELD

Embodiments of the invention generally relate to systems and methods for electrical and electronic component packaging. More specifically, embodiments of the invention concern structural housings used in electronic devices to support and electrically connect multiple components by incorporating internal conductor pathways for delivering power or signals to two or more distinct electrical circuits, while maintaining electromagnetic isolation between them.

### BACKGROUND

Electronic devices often include multiple electrically powered components integrated into a shared system or housing. These components may perform independent functions and operate using different electrical signals or power sources. Structural elements, such as frames, casings, or internal supports, are commonly used to mechanically secure and organize these components within the device.

Power and signal routing to such components is typically achieved using conductors that pass through or around these structural elements. Depending on the application, various materials and configurations are used to manage the spatial arrangement and electrical connectivity of the components and their associated circuitry.

There remains a need in the art for structural systems that support electrically powered components while also accommodating multiple electrical connections within a component housing.

### SUMMARY OF THE INVENTION

One aspect of the invention is directed to a component housing having a structural body with first passages formed in the structural body, the first passages configured to receive first conductors for delivering power to a first electrically powered component via a first electromagnetic (“EM”) field. The structural body can be configured to support the first electrically powered component. The structural body can further include second passages formed in the structural body, the second passages configured to receive second conductors for delivering power to a second electrically powered component via a second EM field that is independent of the first EM field. The structural body can be formed from, or include, an insulating material and is configured to maintain physical and electrical isolation between the first and second passages, such that the first and second EM fields coexist within the component housing without interference.

In some embodiments, the first electrically powered component can be a fan, speaker, screen, microphone, or sensor, and the second electrically powered component can be a high-voltage printed circuit board (PCB). In certain embodiments, the component housing is configured to accommodate conductors such that the first EM field is configured to operate at a voltage below 24 volts and the second EM field is configured to operate at a voltage above 100 volts. In some embodiments, the second conductors are spring-loaded pins.

In one embodiment, the component housing is configured to accommodate insulating members disposed within the second passages, wherein the insulating members are configured to electrically isolate the second conductors from the structural body. In certain embodiments, the structural body comprises a monolithic insulating block having the first and second passages integrally formed therein.

Another aspect of the invention concerns an apparatus having a structural housing comprising first and second passages; a first component electrically coupled via first conductors through the first passages; a second component electrically coupled via second conductors through the second passages. In one embodiment, the first and second conductors respectively carry power via first and second electromagnetic (“EM”) fields. The structural housing is configured to maintain electrical isolation between the first and second EM fields. In some embodiments, the structural housing is a monolithic body of dielectric material. In certain embodiments, the structural housing is configured to maintain a physical separation between the first and second passages.

In one embodiment, the second component can be a high-voltage electrical component. In some embodiments, the first component can be a fan, speaker, microphone, or sensor. In some embodiments, the second conductors can be spring-loaded pins. In certain embodiments, the apparatus further includes insulating sleeves that are disposed within the second passages to electrically isolate the second conductors from the structural housing.

In one embodiment, apparatus is configured to accommodate conductors associated with a first EM field that operates below 24 volts and a second EM field that operates above 100 volts.

Yet another aspect of the invention pertains to a method of operating a component housing. In one embodiment, the method involves delivering power to a first electrically powered component via first conductors extending through first passages in a structural body; delivering power to a second electrically powered component via second conductors extending through second passages in the structural body; wherein the second conductors carry a voltage higher than the first conductors; and maintaining physical and electrical isolation between the first and second conductors such that their respective electromagnetic (“EM”) fields coexist without interference.

In one embodiment, the method involves providing a structural body having a monolithic dielectric material. In some embodiments, the method involves providing a structural body having first and second passages that physically separated by a portion of the structural body to maintain spatial isolation. In certain embodiments, the method can involve providing second conductors that are spring-loaded pins.

In one embodiment, the method can further include disposing insulating sleeves within the second passages to electrically isolate the second conductors from the structural body. In some embodiments, the method can include providing a first electrically powered component that is a fan, speaker, microphone, or sensor. In certain embodiments, the method can include providing a second electrically powered component that is a high-voltage electrical component. In one embodiment, the method involves providing the structural body as part of a sub-assembly configured to manage thermal loads generated by at least one of the first and second components.

In one embodiment, the method involves delivering power to the first electrically powered component includes delivering power via a first EM field operating below 24 volts, and delivering power to the second electrically powered component involves delivering power via a second EM field operating above 100 volts.

### BRIEF DESCRIPTION OF THE DRAWINGS

A more complete understanding of the embodiments, and the attendant advantages and features thereof, will be more readily understood by reference to the following detailed description when considered in conjunction with the accompanying drawings wherein:

FIG. 1 is a schematic diagram illustrating a component housing, as used in an example application environment, according to one embodiment of the invention.

FIG. 2 is a schematic diagram illustrating the component housing of FIG. 1 from a different perspective, according to one embodiment.

FIG. 3 is a front, bottom perspective view of a component housing according to one embodiment of the invention.

FIG. 4 is a top, front perspective view of the component housing of FIG. 3.

FIG. 5 is a bottom, plan view of the component housing of FIG. 3.

FIG. 6 is a front, plan view of the component housing of FIG. 3.

FIG. 7 is a top, plan view of the component housing of FIG. 3.

### DETAILED DESCRIPTION

The specific details of the single embodiment or variety of embodiments described herein are set forth in this application. Any specific details of the embodiments are used for demonstration purposes only, and no unnecessary limitation or inferences are to be understood therefrom.

Before describing exemplary embodiments in detail, it is noted that the embodiments reside primarily in combinations of components related to the system. Accordingly, the device components have been represented where appropriate by conventional symbols in the drawings, showing only those specific details that are pertinent to understanding the embodiments of the present disclosure so as not to obscure the disclosure with details that will be readily apparent to those of ordinary skill in the art having the benefit of the description herein.

Certain embodiments of the invention relate to a component housing configured to support a first electrically powered component and to simultaneously accommodate conductors associated with a second, independent electrical component. The housing can maintain electrical and spatial isolation between the two sets of conductors so that the respective electromagnetic (EM) fields associated with each component can coexist within the same structural body without mutual interference.

In one embodiment, the invention includes a structural body formed from an electrically insulating material. This body may be molded, machined, or otherwise fabricated from a dielectric material such as plastic, ceramic, or a composite. The structural body provides mechanical support for at least one first electrical component, such as a fan, speaker, microphone, or sensor. The component may be attached directly to the surface of the body or may be partially or fully embedded within it, depending on the intended application.

The structural body defines a first set of passages, herein referred to as "first passages," which are configured to receive one or more first conductors. These first conductors are arranged to deliver electrical power or signals to the first electrical component. The first passages may take the form of molded channels, drilled bores, or any other cavities or conduits that allow for the routing of insulated or uninsulated wires, traces, or other conductive elements.

Separately, the structural body also defines a second set of passages, herein referred to as "second passages," which are physically distinct from the first passages and configured to receive second conductors. These second conductors are used to deliver electrical power or signals to a second electrical component that is independent from the first. This second component may or may not be physically located within or on the same housing, and may be connected via an extension of the second conductors exiting the structural body.

The design and layout of the first and second passages are such that physical separation is maintained between the two sets of conductors along their respective routes through the housing. This spatial separation may be achieved by providing a gap between the passages, by encapsulating the conductors in non-conductive material, or by embedding them in distinct regions of the insulating body. In addition to spatial separation, the insulating nature of the structural body ensures electrical isolation between the conductors, thereby preventing crosstalk or interference between the electromagnetic fields generated by each set of conductors.

The configuration enables the structural body to function as a unified housing that supports a first component while simultaneously acting as a conduit or support structure for a second, unrelated electrical system. Importantly, the two sets of conductors and the components they serve operate via electromagnetically independent circuits, and the structure maintains coexistence of the associated EM fields without mutual disruption.

The embodiment described allows for compact, multifunctional housings particularly suited for integration in electronic devices, appliances, and systems where space is limited and electromagnetic compatibility is critical.

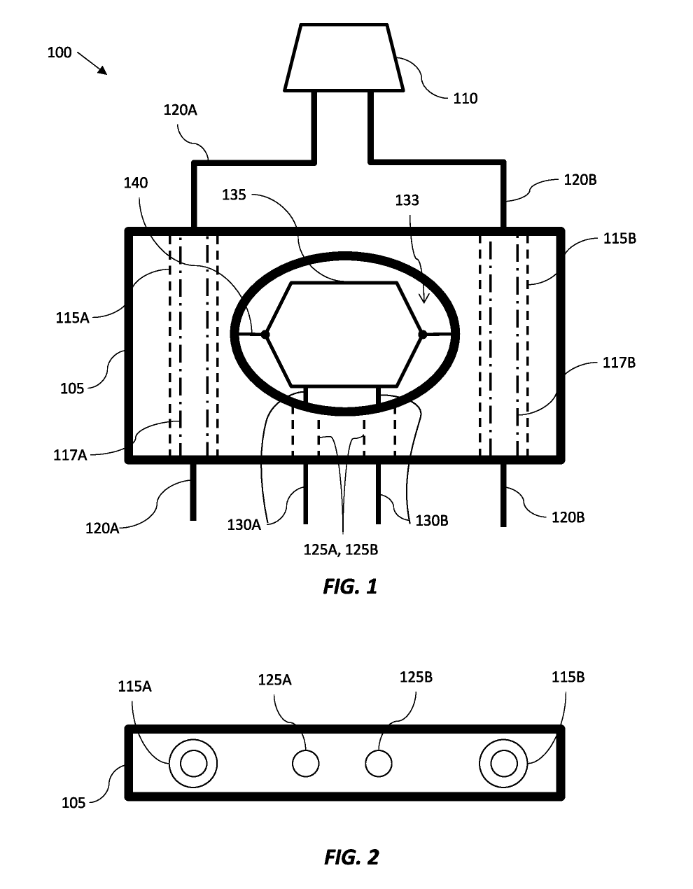

Referencing FIG. 1-2, in one embodiment housing 105 can be configured with first passages 115A, 115B for receiving first conductors 120A, 120B. Housing 105 can be further configured with second passages 125A, 125B for receiving second conductors 130A, 130B. First conductors 120A, 120B can be associated with first electrically powered component 110, and second conductors 130A, 130B can be associated with second electrically powered component 135. Housing 105 can be configured to maintain electrical and spatial isolation between first conductors 120A, 120B and second conductors 130A, 130B so that the respective electromagnetic (EM) fields associated with components 110 and 135 can coexist within the same structural body—namely, housing 105—without mutual interference. In one embodiment, housing 105 can be a structural body formed from an electrically insulating material. This body can be molded, machined, or otherwise fabricated from a dielectric material such as plastic, ceramic, or a composite.

First component 110 can be physically located outside housing 105 and electrically connected via an extension of first conductors 120A, 120B exiting housing 105. First conductors 120A, 120B can be used to deliver electrical power or signals to first electrical component 110, which is independent from second component 135.

Housing 105 can provide mechanical support for at least second electrical component 135, such as a fan, speaker, microphone, or sensor. Component 135 can be attached directly to a surface of housing 105 or can be partially or fully embedded within it, depending on the intended application. In certain embodiments, housing 105 can also be configured to provide mechanical support for second component 135.

Second conductors 130A, 130B can be arranged to deliver electrical power or signals to second electrical component 135. Second passages 125A, 125B can take the form of, for example, molded channels, drilled bores, or any other cavities or conduits that allow for the routing of insulated or uninsulated wires, traces, or other conductive elements.

The design and layout of first passages 115A, 115B and second passages 125A, 125B are such that physical separation is maintained between the two sets of conductors along their respective routes through housing 105. This spatial separation can be achieved, for example, by providing a gap between first passages 115A, 115B and second passages 125A, 125B, by encapsulating the conductors in non-conductive material, or by embedding them in distinct regions of housing 105. In some embodiments, housing 105 can include insulating members 117A, 117B disposed within first passages 115A and 115B, respectively. Insulating members 117A, 117B can assist in maintaining electrical isolation between first conductors 120A, 120B and the surrounding structure or conductors. In addition to spatial separation, the insulating nature of housing 105 itself can further ensure electrical isolation between first conductors 120A, 120B and second conductors 130A, 130B, thereby preventing crosstalk or interference between the electromagnetic fields generated by each set of conductors. In some embodiments, insulating members (not shown) can also be placed in second passages 125A, 125B.

In one embodiment, as illustrated in FIG. 1, housing 105 can include cavity or space 133 configured for receiving or supporting component 135. In one embodiment, structural support members 140 can be used to support or retain component 135 in housing 105. Support members 140 can be integrally formed with housing 105 or separately installed depending on manufacturing or design constraints.

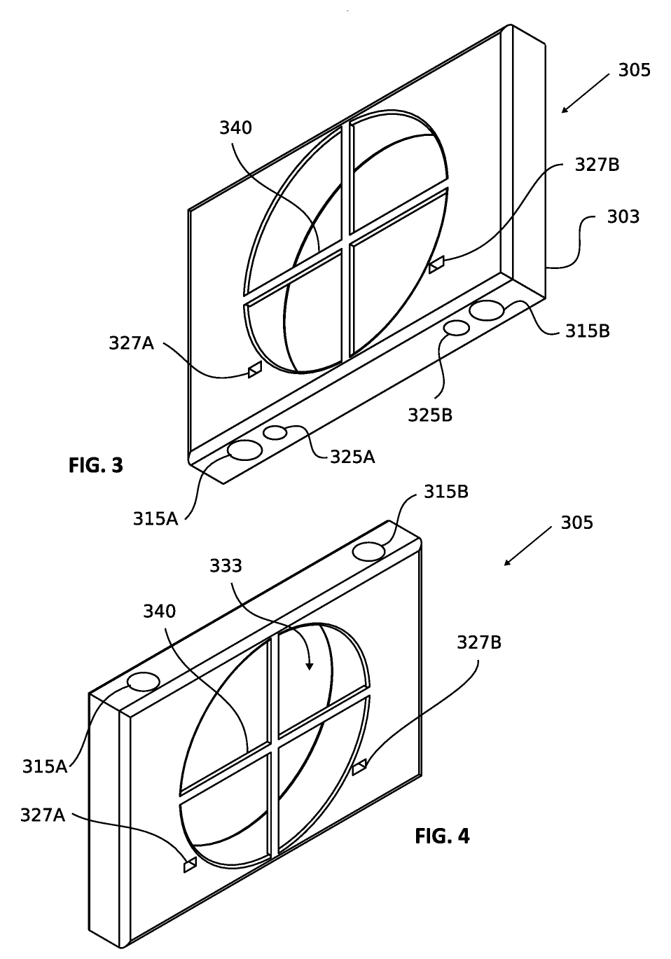

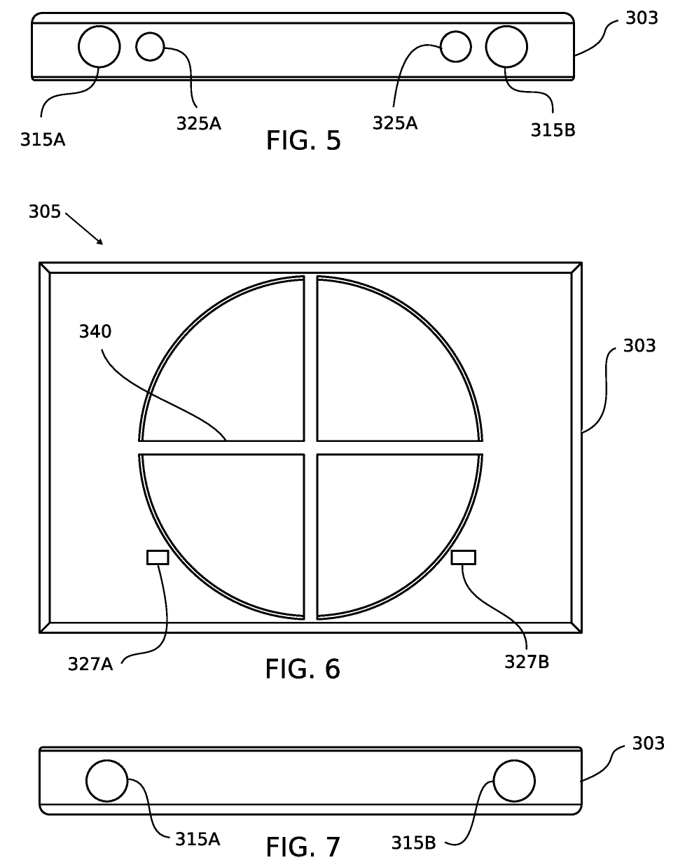

Referencing FIG. 3-7, one embodiment of component housing 305 includes structural body 303. In some embodiments, structural body 303 can be configured with first passages 315A, 315B and second passages 325A, 325B. First passages 315A, 315B can be configured to receive first electrical conductors, which can be (for example) high voltage conductors, that deliver power or signals to a first electrical component. Second passages 325A, 325B can be configured to receive second electrical conductors, which can be (for example) low voltage conductors.

The first conductors are associated with a first electric circuit (or first EM field), and the second conductors are associated with a second electric circuit (or second EM field). The first and second EM fields are independent of each other. In some embodiments, structural body 303 can be configured with, or formed from, an insulating material, and structural body 303 can be thus configured to maintain physical and electrical isolation between the first and second passages, such that the first and second EM fields coexist within component housing 305 without interference.

In certain applications, the first conductors can be associated with circuits operating at relatively low voltages—such as 5V, 12V, or 24V—suitable for components like small fans, sensors, microphones, or speakers. The second conductors, in contrast, can be associated with circuits operating at significantly higher voltages. For example, LED driver circuits, high-voltage PCBs, or industrial components may require voltages in the range of 48V to 150V or higher. In some embodiments, the voltage of the second conductors can exceed 100 volts, and the voltage of the first conductors can be below 24 volts, although other ranges may also be used depending on the intended application. Structural body 303 can be suitably configured to maintain effective isolation between such voltage domains to ensure operational safety and electromagnetic compatibility.

In one embodiment, first passages 315A, 315B are configured to accommodate conductors having an EM field configured to operate at a voltage above 100 volts; and second passages 325A, 325B are configured to accommodate conductors having an EM field configured to operate at a voltage below 24 volts. In certain embodiments, structural body 303 can be a monolithic insulating block having the first and second passages integrally formed therein. However, in other embodiments, structural body 303 can be assembled from separate sections configured to prevent interference between the first and second EM fields. In one embodiment, housing component 305 can include insulating members disposed within the first or second passages, wherein the insulating members are configured to electrically isolate the first or second conductors from structural body 303. In some embodiments, structural body 303 can be formed, at least in part, from a dielectric material.

In one embodiment, structural body 303 can include structural supports 340 and/or space 333 configured to receive, support, or retain an electrical component, such as the second electrical component associated with the second conductors. In some embodiments, structural body 303 can include outlets 327A, 327B which are part of passages 325A, 325B. Outlets 327A, 327B can be provided on the front side (such as shown in FIG. 3-4) of structural body 303, or they can be provided on the back side of structural body 303 (not shown).

Many different embodiments have been disclosed herein, in connection with the above description and the drawings. It will be understood that it would be unduly repetitious and obfuscating to literally describe and illustrate every combination and subcombination of these embodiments. Accordingly, all embodiments can be combined in any way and/or combination, and the present specification, including the drawings, shall be construed to constitute a complete written description of all combinations and subcombinations of the embodiments described herein, and of the manner and process of making and using them, and shall support claims to any such combination or subcombination.

It will be appreciated by persons skilled in the art that the present embodiment is not limited to what has been particularly shown and described hereinabove. A variety of modifications and variations are possible considering the above teachings without departing from the following claims.

1. A component housing comprising:
a structural body configured to support a first electrically powered component;
first passages formed in the structural body, the first passages configured to receive first
conductors for delivering power to the first electrically powered component via a first
electromagnetic (“EM”) field;
second passages formed in the structural body, the second passages configured to
receive second conductors for delivering power to a second electrically powered
component via a second EM field that is independent of the first EM field; and
wherein the structural body comprises an insulating material and is configured to
maintain physical and electrical isolation between the first and second passages, such that
the first and second EM fields coexist within the component housing without interference.

2. The component housing of claim 1, wherein the first electrically powered component
comprises one of a fan, speaker, screen, microphone, or sensor, and the second electrically
powered component comprises a high-voltage printed circuit board (PCB).

3. The component housing of claim 1, wherein the first EM field is configured to operate at a
voltage below 24 volts and the second EM field is configured to operate at a voltage
above 100 volts.

4. The component housing of claim 1, wherein the structural body comprises a monolithic
insulating block having the first and second passages integrally formed therein.

5. The component housing of claim 1, further comprising insulating members disposed within
the second passages, wherein the insulating members are configured to electrically isolate
the second conductors from the structural body.

6. The component housing of claim 1, wherein the second electrically powered component
comprises a high-voltage electrical component.

7. An apparatus comprising:
a structural housing comprising first and second passages;
a first component electrically coupled via first conductors through the first passages;
a second component electrically coupled via second conductors through the second
passages;
wherein the first and second conductors respectively carry power via first and second
electromagnetic (“EM”) fields; and
wherein the structural housing is configured to maintain electrical isolation between
the first and second EM fields.

8. The apparatus of claim 7, wherein the structural housing comprises a monolithic body of
dielectric material.

9. The apparatus of claim 7, wherein the structural housing is configured to maintain a
physical separation between the first and second passages.

10. The apparatus of claim 7, wherein the first component comprises a fan, speaker,
microphone, or sensor.

11. The apparatus of claim 7, wherein the second conductors comprise spring-loaded pins.

12. The apparatus of claim 7, further comprising insulating sleeves that are disposed within the
second passages to electrically isolate the second conductors from the structural housing.

13. The apparatus of claim 7, wherein the first EM field operates below 24 volts and the
second EM field operates above 100 volts.

14. A method of operating a component housing, the method comprising:
delivering power to a first electrically powered component via first conductors extending
through first passages in a structural body;
delivering power to a second electrically powered component via second conductors
extending through second passages in the structural body;
wherein the second conductors carry a voltage higher than the first conductors; and
maintaining physical and electrical isolation between the first and second conductors such
that their respective electromagnetic (“EM”) fields coexist without interference.

15. The method of claim 14, wherein the structural body comprises a monolithic dielectric
material.

16. The method of claim 14, wherein the first passages and second passages are physically
separated by a portion of the structural body to maintain spatial isolation.

17. The method of claim 14, further comprising disposing insulating sleeves within the second
passages to electrically isolate the second conductors from the structural body.

18. The method of claim 14, wherein the first electrically powered component comprises a fan,
speaker, microphone, or sensor.

19. The method of claim 14, wherein delivering power to the first electrically powered
component comprises transmitting power via a first EM field operating below 24 volts, and
delivering power to the second electrically powered component comprises transmitting
power via a second EM field operating above 100 volts.

20. The method of claim 14, wherein the structural body is part of a sub-assembly configured
to manage thermal loads generated by at least one of the first and second components.
